(19) United States
(12) Patent Application Publication
(10) Pub. No.: US 2001/0020730 A1
(43) Pub. Date: Sep. 13, 2001

(54) Integrated circuit configuration, method for producing it, and wafer including integrated circuit configurations

(76) Inventors: Reinhard Stengl, Stadtbergen (DE); Martin Franosch, Munchen (DE); Herbert Schafer, Hohenkirchen-Siegertsbrunn (DE); Volker Lehmann, Munchen (DE); Hans Reisinger, Grunwald (DE); Hermann Wendt, Grasbrunn (DE)

Correspondence Address: LERNER AND GREENBERG, P.A., Post Office Box 2480, Hollywood, FL, 33022-2480, US

(21) Appl. No.: 09/752,919

(22) Filed: Jan. 2, 2001

Related U.S. Application Data
(63) Continuation of application No. PCT/DE99/01934, filed on Jul. 1, 1999.

(30) Foreign Application Priority Data
Jul. 2, 1998 (DE) 198 29 629.0

(51) Int. Cl. H01L 29/30; H01L 23/58

(52) U.S. Cl. 257/617; 257/629

(57) ABSTRACT

An integrated circuit configuration includes a structure, a p-n junction, and a defect plane disposed such that each of a plurality of straight lines, that intersect or touch the structure and the p-n junction, intersect the defect plane. This prevents unwanted leakage currents through the p-n junction and increases a retention time in a DRAM cell configuration. A wafer configuration and a method of producing an integrated circuit configuration are also provided.

### CROSS-REFERENCE TO RELATED APPLICATION:

This application is a continuation of copending International Application No. PCT/DE99/01934, filed Jul. 1, 1999, which designated the United States.

### BACKGROUND OF THE INVENTION

1. Field of the Invention

The invention relates to an integrated circuit configuration, a method for producing it and to a wafer including a number of integrated circuit configurations.

Leakage currents in semiconductor components are generally unwanted since they lead to a higher power consumption and to deviations from the ideal profile of characteristics of the semiconductor components.

In some memory cell configurations, the intensity of the leakage currents determines the maximum time interval after which information stored in a memory cell must be refreshed. This time interval is also called retention time. An increase in retention time is desirable particularly in memory cell configurations which are intended for battery-operated devices such as, e.g. portable computers.

The memory cell has a so-called variable retention time (VRT) if the retention time changes with time (see P. J. Restle et al., “DRAM Variable Retention Time”, IEDM 92, pages 807 to 810). There is a strong correlation between the occurrence of VRT effects and the occurrence of defects in the crystal structure of a silicon substrate in which the memory cell configuration is provided.

From D. Chidambarrao et al., “Stresses in Silicon Substrates Near Isolation Trenches”, J. Appl. Phys. 70(9), 1991, pages 4816 to 4821, it is known that isolation trenches, i.e. insulating structures provided in flat recesses of a silicon substrate, create mechanical stresses in the substrate which can generate defects in the form of dislocations.

From R. Stengl et al., “High Pressure Oxidation Induced Stress in Submicron Trench Structures”, Appl. Phys. Lett. 68 (20), 1996, pages 2843 to 2845, is known that thermal oxidation of surfaces of recesses in a substrate in which storage capacitors of DRAM cell configurations are generated, causes high stresses in the substrate.

From T. O. Sedgwick et al., “Growth of Facet-Free Selective Silicon Epitaxy at Low Temperature and Atmospheric Pressure”, J. Electrochem. Soc., Vol. 138, No. 10, 1991, pages 3042 to 3047, it is known that in the case of epitaxy of silicon on a silicon substrate between oxide islands, a lower defect density is achieved if the oxide islands are provided along an <100> direction of the crystal lattice of the substrate than if the oxide islands are provided along an <110> direction. These defects are so-called microtwin defects.

In B. El-Kareh et al., “The Evolution of DRAM Cell Technology”, Solid State Technology, 1997, pages 89 to 101, a DRAM cell configuration is described in which two planar transistors are provided between two storage capacitors provided in recesses. The two transistors in each case exhibit a first source/drain region which is connected to the respective adjoining storage capacitor. Between channel regions of the two transistors, a second source/drain region is provided which is common to both transistors. The second source/drain region is connected to a bit line. The transistors are driven via word lines which extend perpendicularly to the bit line. Outside the transistors and the storage capacitors, an insulating structure disposed in a flat recess is provided.

In memory cell configurations, in particular, components are provided on a surface of a silicon substrate along lines which extend parallel to a y-axis or to an x-axis perpendicular to the y-axis, at periodically repetitive distances from one another. The y-axis corresponds, e.g. to the <110> direction of the crystal lattice of the substrate. This configuration is selected since characteristics of transistors depend on the orientation of the channel run with respect to the crystal lattice. In semiconductor production, a number of identical circuit configurations are usually generated on a disk-shaped silicon substrate, a so-called wafer. To generate such circuit configurations, photoresist masks, among others, are applied to the wafer in a machine for phototechnology. To facilitate the adjustment of the photoresist masks with respect to the crystal lattice, the wafer usually has a flat surface, a so-called flat through the use of which the shape of the wafer deviates from a flat cylinder at the relevant location. The flat corresponds to a (110) plane of the crystal lattice.

### SUMMARY OF THE INVENTION

It is accordingly an object of the invention to provide an integrated circuit configuration which has reduced leakage currents and in particular at least one component having at least one p-n junction, in which the leakage currents for the p-n junction are reduced in comparison to the prior art.

It is a further object of the invention to provide a method of producing such an integrated circuit configuration. It is yet another object of the invention to provide a wafer including a number of such integrated circuit configurations.

With the foregoing and other objects in view there is provided, in accordance with the invention, an integrated circuit configuration, including:

a substrate having a crystal structure with defects and defining a defect plane, the defects extending at least partly in the defect plane;

a structure provided in the substrate such that the defects can adjoin the structure;

a first doped region adjoining the structure and having a first conductivity type;

a second doped region adjoining the first doped region and having a second conductivity type opposite the first conductivity type;

a boundary region provided between the first doped region and the second doped region, the boundary region forming a p-n junction; and

the structure, the p-n junction, and the defect plane being disposed such that each of a plurality of straight lines, that intersects or touches the structure and the p-n junction, intersects the defect plane.

According to another feature of the invention, the substrate has a surface. The structure defines a first projection onto the surface, the p-n junction defines a second projection onto the surface, the first and second projections define connecting lines therebetween. The structure and the p-n junction are provided such that a first limiting straight line touches but does not intersect the first and second projections and such that the first limiting straight line intersects the connecting lines between the first and second projections. The structure and the p-n junction are provided such that a second limiting straight line intersects the first limiting straight line at an intersection point thereof and touches but does not intersect the first and second projections, and such that the second limiting straight line intersects the connecting lines between the first and second projections. The first limiting straight line and the second limiting straight line delimit two areas, the structure and the p-n junction are respectively provided in the two areas, and the defect plane defines a third projection onto the surface, the third projection being a straight line extending outside the two areas and through the intersection point of the first and second limiting straight lines.

According to yet another feature of the invention, the surface defines an x-axis and a y-axis perpendicular to the x-axis, the x-axis and the y-axis extend in the surface and intersect one another at the intersection point. Components are provided at the surface along lines extending parallel to the y-axis or the x-axis, the components are spaced from one another by periodically repetitive distances and include the structure and the p-n junction as parts. The p-n junction and the structure are provided along the y-axis, the two areas have respective centers, the structure and the p-n junction are disposed such that the y-axis divides the two areas in the respective centers. The first limiting straight line includes a given part having a beginning and an end at points where the first limiting straight line respectively touches the first projection and the second projection, and the third projection is defined by a rotation of the y-axis about an angle between arctan c/a and (180°-arctan c/a), where c is a first length of a fourth projection of the given part of the first limiting straight line onto the x-axis and where a is second length of a fifth projection of the given part of the first limiting straight line onto the y-axis.

According to a further feature of the invention, a DRAM cell configuration is provided, the components being storage capacitors and planar transistors, the storage capacitors being provided in pairs. The structure is a first one of the storage capacitors, a first and a second one of the planar transistors are provided between the first one of the storage capacitors and a second one of the storage capacitors, the first one of the storage capacitors and the second one of the storage capacitors form one of the pairs. The first doped region acts as a first source/drain region of the first one of the transistors, the first source/drain region is connected to the first one of the storage capacitors. The second doped region acts as a channel region for the first one of the transistors. The second one of the planar transistors has a further channel region and has a further first region as a further first source/drain region connected to the second one of the storage capacitors. A common second source/drain region is provided for the first and the second one of the planar transistors. The common second source/drain region is provided between the channel region and the further channel region. The second projection has an edge parallel to the x-axis, the first one and the second one of the storage capacitors define connecting lines therebetween, the connecting lines are disposed in a given region. The second projection does not extend beyond the given region. The p-n junction has a length substantially equal to the first length c, and the p-n junction and the first one of the storage capacitors are spaced apart by a given distance, the given distance extends in a direction parallel to the y-axis and is substantially equal to the second length a.

According to another feature of the invention, the substrate contains monocrystalline silicon, and the defects are described with (−1,1,z) Burgers vectors located in the defect plane, where z is an integral number.

With the objects of the invention in view there is also provided, a wafer configuration, including:

a wafer including a substrate having a surface;

the substrate being a semiconductor disk and having a marking indicating a course of a y-axis;

the substrate having a crystal structure with defects and defining a defect plane, the defects extending at least partly in the defect plane;

a plurality of integrated circuit configurations provided in the substrate;

each of the integrated circuit configurations having components provided along lines extending parallel to the y-axis or an x-axis perpendicular to the y-axis, the components being provided at the surface and being spaced apart from one another by periodically repetitive distances;

a first one of the components including a structure provided in the substrate;

a second one of the components including a first doped region and a second doped region, the first doped region adjoining the structure and having a first conductivity type, the second doped region having a second conductivity type, the first and second doped regions forming a p-n junction;

the p-n junction and the structure being provided along the y-axis;

the structure defining a first projection on the surface of the substrate, the p-n junction defining a second projection on the surface of the substrate, the defect plane defining a third projection onto the surface, the first and second projections defining connecting lines therebetween;

the structure and the p-n junction being provided such that a first limiting straight line touches but does not intersect the first and second projections and such that the first limiting straight line intersects the connecting lines between the first and second projections;

the structure and the p-n junction being provided such that a second limiting straight line intersects the first limiting straight line at an intersection point thereof and touches but does not intersect the first and second projections, and the structure and the p-n junction being provided such that the second limiting straight line intersects the connecting lines between the first and second projections;

the x-axis and the y-axis extending in the surface and intersecting one another at the intersection point;

the first limiting straight line and the second limiting straight line delimiting two areas, the structure and the p-n junction being respectively provided in the two areas;

the two areas having respective centers, the structure and the p-n junction being disposed such that the y-axis divides the two areas in the respective centers;

the first limiting straight line including a given part having a beginning and an end where the first limiting straight line respectively touches one of the first projection and the second projection;

the given part of the first limiting straight line defining a fourth projection onto the x-axis and a fifth projection onto the y-axis; and

the third projection being a straight line and being defined by a rotation of the y-axis about an angle between arctan c/a and (180°-arctan c/a), where c is a first length of the fourth projection and where a is a second length of the fifth projection.

With the objects of the invention in view there is also provided, a wafer configuration, including:

a wafer including a substrate having a surface;

the substrate being a semiconductor disk and having a marking indicating a course of a defect plane;

the substrate having a crystal structure with defects extending at least partly in the defect plane;

a plurality of integrated circuit configurations provided in the substrate;

each of the integrated circuit configurations having components provided along lines extending parallel to a y-axis or an x-axis perpendicular to the y-axis, the components being spaced apart from one another by periodically repetitive distances;

a first one of the components including a structure provided in the substrate;

a second one of the components including a first doped region and a second doped region, the first doped region adjoining the structure, the first and second doped regions forming a pn junction;

the p-n junction and the structure being provided along the y-axis;

the structure defining a first projection on the surface of the substrate, the p-n junction defining a second projection on the surface of the substrate, the defect plane defining a third projection onto the surface, the first and second projections defining connecting lines therebetween;

the structure and the p-n junction being provided such that a first limiting straight line touches but does not intersect the first and second projections and such that the first limiting straight line intersects the connecting lines between the first and second projections;

the structure and the p-n junction being provided such that a second limiting straight line intersects the first limiting straight line at an intersection point thereof and touches but does not intersect the first and second projections, and the structure and the p-n junction being provided such that the second limiting straight line intersects the connecting lines between the first and second projections;

the x-axis and the y-axis extending in the surface and intersecting one another at the intersection point;

the first limiting straight line and the second limiting straight line delimiting two areas, the structure and the p-n junction being respectively provided in the two areas;

the two areas having respective centers, the structure and the p-n junction being disposed such that the y-axis divides the two areas in the respective centers;

the first limiting straight line including a given part having a beginning and an end where the first limiting straight line respectively touches one of the first projection and the second projection;

the given part of the first limiting straight line defining a fourth projection onto the x-axis and a fifth projection onto the y-axis; and

the third projection being a straight line and being defined by a rotation of the y-axis about an angle between arctan c/a and (180°-arctan c/a), where c is a first length of the fourth projection and where a is a second length of the fifth projection.

With the objects of the invention in view there is also provided, a method for producing an integrated circuit configuration, the method includes the steps of:

providing a substrate having a marking illustrating a course of a defect plane, the substrate exhibiting a crystal structure with defects extending at least in sections in the defect plane;

providing a surface of the substrate perpendicular to the defect plane;

producing a circuit configuration in the substrate by using masks on the surface;

providing the masks as part of a layout, the layout providing components of the circuit configuration spaced apart from one another by periodically repetitive distances, and the layout providing the components of the circuit configuration along lines extending parallel to one of an x-axis and a y-axis perpendicular to the x-axis;

providing a first one of the components as a structure, the defects being generated by generating the structure;

providing a p-n junction formed by a first doped region and a second doped region, the first doped region adjoining the structure, and the p-n junction being part of a second one of the components; and

adjusting, in a machine for phototechnology, the masks with respect to the substrate by using the marking of the substrate and by rotating the layout and thus the masks with respect to a projection of the defect plane onto the surface of the substrate such that the y-axis and the projection of the defect plane enclose an angle so that a straight line, which touches but does not intersect the structure and the p-n junction, intersects connecting lines between the structure and the p-n junction and extends essentially parallel to the projection of the defect plane.

With the objects of the invention in view there is also provided, a method for producing an integrated circuit configuration, the method includes the steps of:

providing a substrate having a marking indicating a course of a u-axis, the substrate exhibiting a crystal structure with to defects extending at least in sections in a defect plane extending perpendicular to a surface of the substrate, a projection of the defect plane onto a surface of the substrate being a straight line, the u-axis and the projection of the defect plane enclosing a given angle;

producing a circuit configuration in the substrate by using masks;

providing the masks as part of a layout, the layout providing components of the circuit configuration spaced apart from one another by periodically repetitive distances, and the layout providing the components of the circuit configuration along lines extending parallel to one of a y-axis and an x-axis perpendicular to the x-axis;

providing a first one of the components as a structure, the defects being generated by generating the structure;

providing a p-n junction formed by a first doped region and a second doped region, the first doped region adjoining the structure, and the p-n junction being part of a second one of the components;

providing the structure and the p-n junction such that a straight line, which touches but does not intersect the structure and the p-n junction and intersects connecting lines between the structure and the p-n junction, and the y-axis enclose the given angle; and

adjusting, in a machine for phototechnology, the masks with respect to the substrate by using the marking of the substrate such that the y-axis defined by the layout and thus by the masks and the u-axis defined by the substrate correspond to one another.

According to another mode of the invention, a plurality of identical circuit configurations are produced on the substrate.

Other features which are considered as characteristic for the invention are set forth in the appended claims.

Although the invention is illustrated and described herein as embodied in an integrated circuit configuration, a method for producing it and a wafer including a number of integrated circuit configurations, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic top view of a memory cell;

FIG. 2 is a schematic illustration of projections onto a surface of a substrate in relationship to limiting straight lines;

FIG. 3 is a top view of a DRAM cell configuration as calculated by a computer simulation and represents the course of the defects in a substrate;

FIG. 4 is a top view of a DRAM cell configuration as calculated by a computer simulation and represents the course of the defects in a substrate according to the invention;

FIG. 5 is a partial diagrammatic top view of a DRAM cell configuration with storage capacitors, transistors with p-n junctions, an x-axis, a y-axis, and a projection of a defect plane onto a surface of a substrate;

FIG. 6 is a top view of a first wafer having a marking which illustrates the course of a y-axis, a projection of a defect plane, cell configurations, and a mask; and

FIG. 7 is a top view of a second wafer having a marking which illustrates a course of a defect plane, a y-axis, cell configuration, and a mask.

### DESCRIPTION OF THE PREFERRED EMBODIMENTS

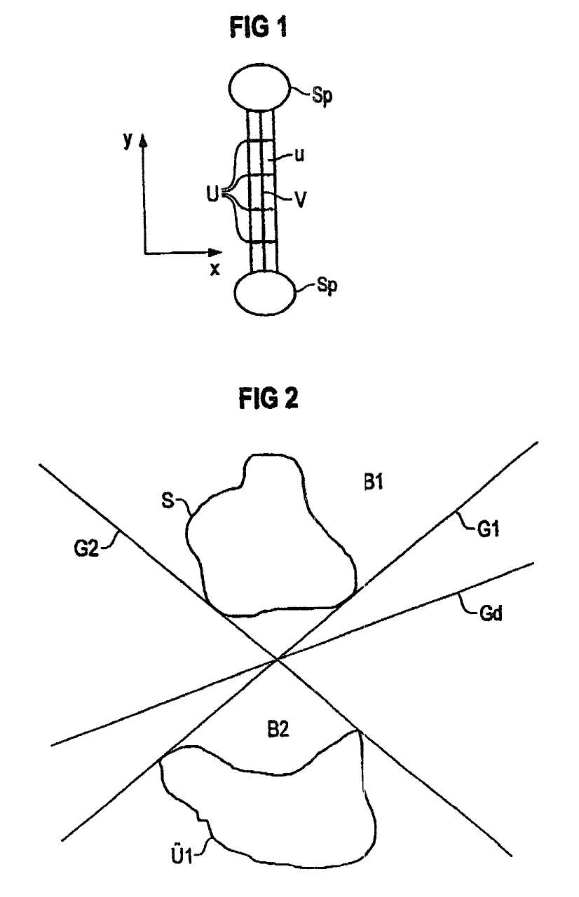

The invention is described in detail with reference to the figures of the drawings, which are not true to scale. The invention is based on an investigation of memory cells of a DRAM cell configuration, which are provided in a silicon substrate and which exhibit VRT (Variable Retention Time) effects. The layout of the DRAM (Dynamic Random Access Memory) cell configuration investigated corresponded to the above-mentioned DRAM cell configuration from the document by El-Kareh et al. quoted above. A connection line between two mutually adjacent storage capacitors Sp, which intersects two planar transistors provided between them, extends parallel to a y-axis y (see FIG. 1). Storage capacitors Sp and transistors of the DRAM cell configuration are provided along lines which extend parallel to the y-axis y or to an x-axis x which is perpendicular to the y-axis and is located in one surface, at periodically repetitive distances from one another. Edges of p-n junctions U of the transistors, via which channel currents can flow, extend parallel to the x-axis x. The y-axis y corresponds to the <110> direction of the crystal lattice of the silicon substrate. Using transmission electron microscopy, it was surprisingly found that almost all dislocation defects V which occurred are associated with the <−1,1,z> Burgers vectors, where z is an integral number. The dislocation defects V extend parallel to the <−1,1,z> Burgers vectors and often extend from one storage capacitor Sp to the other (see FIG. 1). Since the surface of the substrate is perpendicular to the plane in which the Burgers vectors are located, the dislocations V appear as straight lines. It was also found that in the memory cells which display VRT effects, the dislocation defects V intersect the p-n junctions U of the associated transistors.

The dislocation defects presumably generate leakage currents which lead to the VRT effect.

FIG. 1 shows a top view of one of the memory cells affected. Elliptical structures are the storage capacitors Sp. Any elongated area u which extends from one storage capacitor Sp to the other includes the transistors. The lines extending parallel to the x-axis, which subdivide the elongated area u, are the p-n junctions U. The dislocation V is a line which extends parallel to the y-axis y and intersects the elongated area u.

The invention is based on the finding that dislocation defects which intersect a p-n junction can cause leakage currents and that starting points or end points of the defects are located on surfaces of the substrate.

An integrated circuit configuration according to the invention is provided in a substrate in which defects extend at least in sections in a plane (called defect plane in the text that follows) of a crystal lattice of the substrate. The reason for the course of the defects can lie in the symmetry characteristics of the crystal lattice. Other reasons can be the chemical composition of the substrate and the configuration of components in the substrate, i.e. the layout.

The manner in which the circuit configuration is produced can also influence the origin and the courses of the defects.

The defects can be dislocations such as, e.g. helical dislocations. As an alternative, the defects can be stacking faults.

The substrate can contain, for example, monocrystalline silicon. The substrate can also contain other elements such as, for example, germanium which are suitable for the circuit configuration.

The substrate can exhibit a crystalline structure including a diamond lattice with fcc base. Substrates having other types of lattice are also within the scope of the invention.

The integrated circuit configuration includes at least one first component having a structure provided in the substrate, which can be adjoined by the defects, and a second component having at least one p-n junction. The defects can be created by generating the structure. The p-n junction is adjacent to the structure in such a manner that, for reasons of distance and/or configuration, it is not impossible that defects which are caused by the structure can propagate through the substrate and can intersect the p-n junction. The p-n junction is formed, for example, by a boundary area between a first region of the substrate which is doped by a first type of conductivity and which is adjoined by the structure, and by a second region of the substrate which is doped by a second type of conductivity which is opposite to the first type of conductivity. The p-n junction and the structure meet the following conditions: they are provided relative to the crystal lattice in such a manner that each straight line which intersects or touches the structure and intersects or touches the p-n junction intersects the defect plane. Since starting points of the defects which are formed by the structure are located on edges of the structure, the sections of the defects which extend in the defect plane do not intersect the p-n junction. As a consequence, these sections do not contribute to leakage currents so that leakages currents are reduced in comparison with the prior art.

If the defects exhibit other sections which preferably extend parallel to another defect plane, the following additional condition is met: each of the straight lines which intersect or touch the structure and intersect or touch the p-n junction intersect the further defect plane.

The structure and the p-n junction can be parts of the first component. In this case, the first component and the second component coincide.

The first component can be, e.g. a capacitor or a contact pad. The capacitor can be provided in a recess of the substrate or on the substrate. The second component can be, for example, a transistor, a diode or a line (e.g. ground).

In an advantageous possibility for meeting the above-mentioned condition, projections on a surface of the substrate are considered instead of three-dimensional extensions. This simplifies the practical fulfillment of the condition. The condition is fulfilled if no straight line which extends parallel to the surface and which intersects or touches a projection of the structure onto the surface S and intersects or touches a projection of the p-n junction onto the surface U1 extends parallel to straight lines which are located in a projection of the defect plane onto the surface (see FIG. 2).

The defect plane is preferably perpendicular to the surface. In this case, the projection of the defect plane is a single straight line.

In the text which follows, the advantageous possibility of meeting the above-mentioned condition is explained in other words. There are exactly two limiting straight lines G1, G2 which in each case touch both the injection of the structure S and projection of the p-n junction U1 without intersecting these projections and which in each case intersect connecting lines between projections (see FIG. 2). The two limiting straight lines G1, G2 intersect at a point of intersection. The projection of the p-n junction U1 and the projection of the structure S are located in two areas B1, B2 of the surface which are limited by the limiting straight lines G1. The condition is met if a straight line Gd which is parallel to the projection of the defect plane and which passes through the point of intersection is located outside the two areas B1, B2 (see FIG. 2). If there are other defect planes, a corresponding straight line is also outside the area.

The projection of the courses of the sections of the defects extend parallel to the straight line Gd, but do not intersect the point of intersection since the defects have their origin on edges of the structure. Since the limiting straight lines G1, G2 virtually connect extreme points of projection of the p-n junction U1 and the projection of the structure S with one another, the defects cannot intersect the p-n junction. FIG. 2 illustrates the situation described above through the use of exemplary dimensions of the projections and an exemplary position of the defect plane.

Meeting the condition by taking into consideration the projections is scarcely a restriction in comparison with the consideration of the three-dimensional extensions with regard to the possible configurations of the components, especially if cross sections of the structure parallel to the surface are essentially identical and cross sections of the p-n junction which are parallel to the surface are essentially identical.

It is within the scope of the invention if the circuit configuration exhibits further components. The components are provided along lines which extend parallel to the y-axis or to an x-axis which is perpendicular to the y-axis, at periodically repetitive distances from one another, the x-axis and the y-axis extending parallel to the surface of the substrate. The p-n junction and the structure are provided along the y-axis. The structure and the p-n junction are such that the y-axis divides the two areas which are limited by the limiting straight lines in their centers. In other words, the y-axis represents a bisecting line of an angle enclosed by the limiting straight lines. In the text which follows, c designates the length of a projection onto the x-axis of a part of one of the limiting straight lines, the start and end of which are points at which the limiting straight line touches the structure or the p-n junction, respectively. The length of the projection of the part of the limiting straight line onto the y-axis is designated by a. The condition is met when the defect plane, and thus the crystal structure, is aligned with respect to the x-axis and the y-axis in such a manner that the projection of the defect plane arises from a rotation of the y-axis by an angle which is within an area between (arctan c/a) and (180°-arctan c/a). If there are other defect planes, projections of the further defect planes are also obtained from a rotation of the y-axis by further angles in the above-mentioned range.

Such a circuit configuration is, for example, a DRAM cell configuration. The components are storage capacitors and transistors. The structure is one of the storage capacitors which can be provided in recesses. The p-n junction is part of one of the transistors. The first region and the second region which form the p-n junction are a first source/drain region and a channel region of the transistor. Cross sections of the storage capacitors which are parallel to the surface are essentially identical and e.g. approximately circular. Cross sections of the p-n junctions which are parallel to the surface are essentially identical. A diameter of the storage capacitor which is parallel to the x-axis is at least as large as one dimension of the p-n junction which is parallel to the x-axis. An edge of the projection of the p-n junction extends e.g. at least partially parallel to the x-axis. Outside the transistors and the storage nodes, an insulating structure can be provided at which the defect courses can end. The insulating structure defines areas of the substrate.

The DRAM cell configuration can correspond to the one from the above-mentioned document by El-Kareh et al.

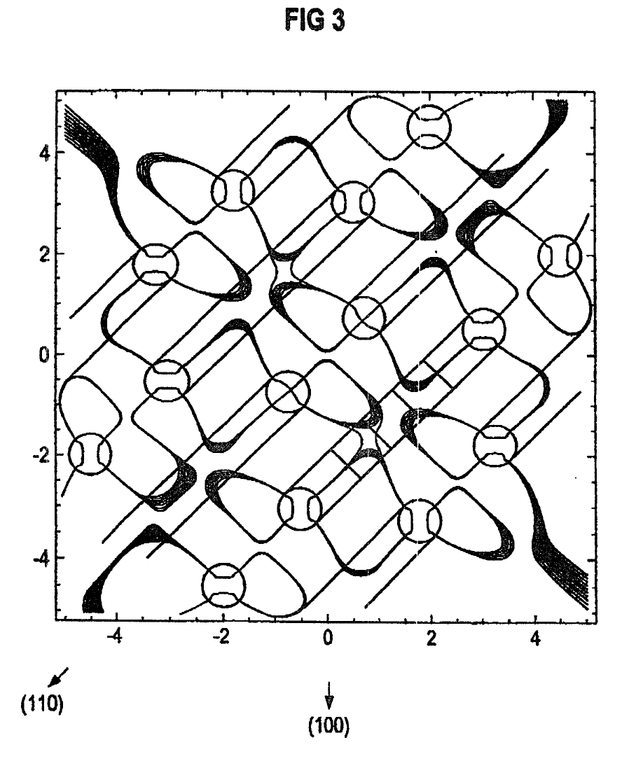

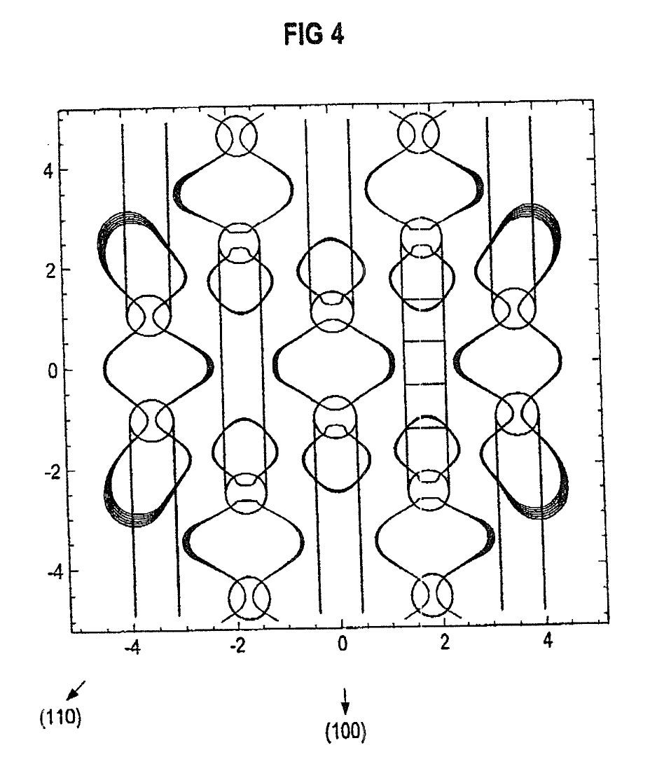

It is within the scope of the invention if the substrate contains monocrystalline silicon and the defect plane is parallel to the <−1,1,z> directions of the crystal lattice, where z is an integral number. This embodiment according to the invention is based on the above-described finding, that dislocation defects in the silicon substrate can be associated with the <−1,1,z> Burgers vectors. Through the use of exemplary dimensions of the DRAM cell configuration in a silicon substrate, computer simulations confirm that the fulfillment of the condition leads to the dislocation defects not intersecting the p-n junctions. FIG. 3 shows a top view of the DRAM cell configuration, calculated by a computer simulation, which represents the course of the defects in such a substrate, where the condition is not met. In this arbitrary example the angle is 0°. The circular structures are the storage capacitors, the transistors are located in the elongated areas between pairs of the storage capacitors, and the remaining lines reproduce the courses of the defects. In one of the elongated areas, p-n junctions are drawn which subdivide the elongated area. The projection of the defect plane which extends parallel to the <−1,1,z> directions, and a projection of another defect plane which extends perpendicular to the projection of the defect plane can be seen. The further defect plane can be effectively eliminated in such a substrate by providing in the substrate outside the transistor structures through which the defects cannot extend. The structures can be, for example, insulating structures which are provided in recesses of the substrate. FIG. 4 shows a top view, calculated by a computer simulation, of the DRAM cell configuration which represents the course of the defects in such a substrate, where the condition is met. In this arbitrary example, the angle is 45°. As may be seen, the p-n junctions are not intersected by the defects.

In a first embodiment of a wafer according to the invention, the wafer includes a substrate which exhibits a marking which illustrates the course of the y-axis. Provided in the substrate are a number of circuit configurations according to the invention which are identical to one another, the components of each circuit configuration being provided along lines which extend parallel to the y-axis or to the x-axis at periodically repetitive distances from one another.

The marking can be, for example, a flat or what is generally called a notch.

If the substrate includes monocrystalline silicon, the surface of the flat extends parallel to the <100> direction of the crystal lattice.

An embodiment of a method according to the invention for producing the integrated circuit configuration according to the invention, where the components of the circuit configuration are provided along lines which extend parallel to the y-axis or to the x-axis at periodically repetitive distances from one another, deviates from conventional production methods in particular in that the substrate of the circuit configuration used exhibits a marking which illustrates the course of the y-axis. Photoresist masks of e.g. known layouts are adjusted in a conventional manner with respect to the marking of the substrate. The circuit configuration is created, due to the use of this substrate, in such a manner that defects do not intersect the p-n junction. Naturally, novel layouts can also be used.

For a method for generating a number of circuit configurations according to the invention which are identical to one another, the substrate can be a wafer according to the first embodiment. The circuit configurations generated on the wafer are then separated.

In a second embodiment of the wafer according to the invention, the wafer includes a substrate which exhibits a marking, the course of which illustrates the defect plane. In the substrate, a number of circuit configurations according to the invention, which are identical to one another, are provided, the components of each circuit configuration being provided along lines which extend parallel to the y-axis or to the x-axis at periodically repetitive distances from one another.

The marking can be constructed, for example, as a flat or as a notch.

If the substrate includes monocrystalline silicon, the surface of the flat extends parallel to the <110>direction of the crystal lattice.

A further embodiment of the method according to the invention for producing the integrated circuit configuration according to the invention, where the components of the circuit configuration are provided along lines which extend parallel to the y-axis or to the x-axis at periodically repetitive distances from one another, deviates from conventional production methods in that, in particular, a layout is used which results, e.g. from a known layout by a rotation about an angle with respect to the y-axis so that the defects do not intersect the p-n junction. A substrate of the circuit configuration which is used exhibits a marking which illustrates the course of the defect plane. Photoresist masks are created which can correspond to known photoresist masks apart from the orientation with respect to the marking. Naturally, novel layouts can also be used.

For a method for generating a number of circuit configurations according to the invention which are identical to one another, the substrate can be a wafer according to the second embodiment. The circuit configurations generated on the wafer are then separated.

For the embodiments of the method and of the wafer described, the variations described for the circuit configuration are also possible.

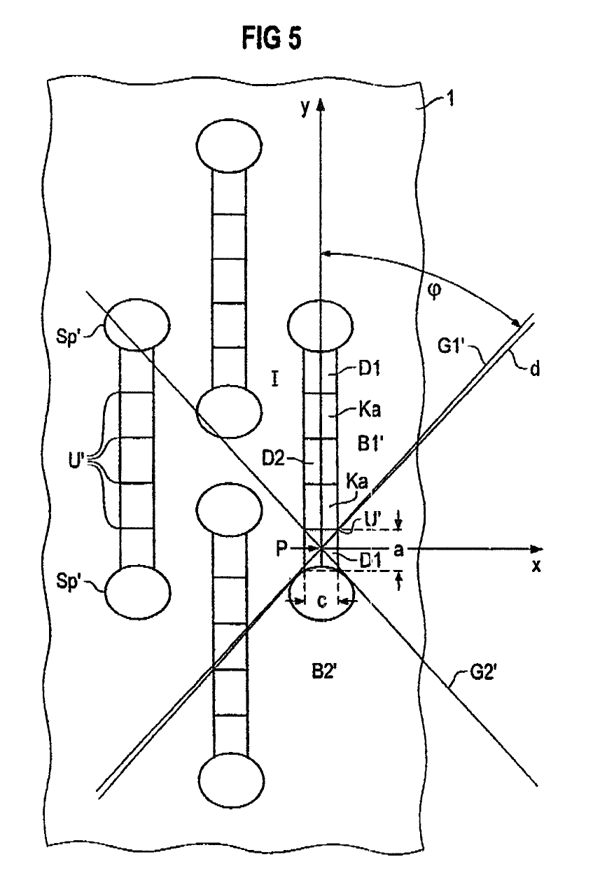

In a first embodiment, a first substrate 1 in which a DRAM cell configuration is provided, includes monocrystalline silicon. Storage capacitors Sp′ and transistors are generated. Storage cells of the DRAM cell configuration in each case include one of the storage capacitors Sp′ and one of the planar transistors (see FIG. 5). Along a y-axis y which extends in a surface of the first substrate 1, mutually adjacent storage capacitors Sp′ form pairs. Between the two storage capacitors Sp′ of each pair, two transistors are provided. First source/drain regions D1 of the transistors are connected to the in each case adjacent ones of the storage capacitors Sp′. The two transistors share a common source/drain region D2. Between in each case one of the first source/drain regions Dl and a second source/drain region D2, a channel region Ka is provided. Boundary areas between the channel regions Ka and the source/drain regions D1, D2 form pn junction U′. Cross sections of the storage capacitors Sp′ which are parallel to the surface are essentially circular. Diameters of the cross sections of the storage capacitors Sp′ are about 600 nm. An x-axis x extends perpendicular to the y-axis y and in the surface. Dimensions of the p-n junctions which are parallel to the x-axis x are about 250 nm. Dimensions of the first source/drain regions Dl parallel to the y-axis y are about 250 nm. A dimension of the second source/drain region D2 which is parallel to the y-axis y is about 250 nm. Dimensions of the channel regions Ka which are parallel to the y-axis are about 250 nm. In the area of the surface, an about 250 nm-thick insulating structure I is located outside the transistors and the storage capacitors Sp′.

A first limiting straight line G1′ extending in the surface touches one of the storage capacitors Sp′ and an adjacent one of the p-n junctions U′. The first limiting straight line G1′ intersects the first source/drain region D1. A second limiting straight line G2′ extending in the surface intersects the first limiting straight line G1′ at a point of intersection P and touches the capacitor Sp′ and the p-n junction U′. The two limiting straight lines G1′, G2′ limit two areas B1′, B2′ in which the storage capacitor Sp′ and the p-n junction U′ are provided. The y-axis y divides the two areas B1′, B2′ in their centers (see FIG. 5).

A projection c of a part of the first limiting straight line G1′, the starting and end points of which are located on the storage capacitor Sp′ and, respectively, on the p-n junction U′, onto the y-axis y is about 250 nm. A projection a of the part of the first limiting straight line G1′ onto the x-axis x is about 250 nm. The first limiting straight line G1′ and the y-axis y enclose an angle φ which is arctan c/a=45° (see FIG. 5).

The y-axis y and the x-axis x intersect at the point of intersection P. The crystal lattice of the first substrate 1 is provided with respect to the y-axis y and the x-axis x in such a manner that a projection of the <−1,1,z> directions, which defines a defect plane d, onto the surface is a straight line and originates from a rotation of the y-axis y by an angle which is not very much greater than the angle φ, e.g. 46°. The projection of the <−1,1,z> direction is thus approximately on the first limiting straight line G1′ (see FIG. 5).

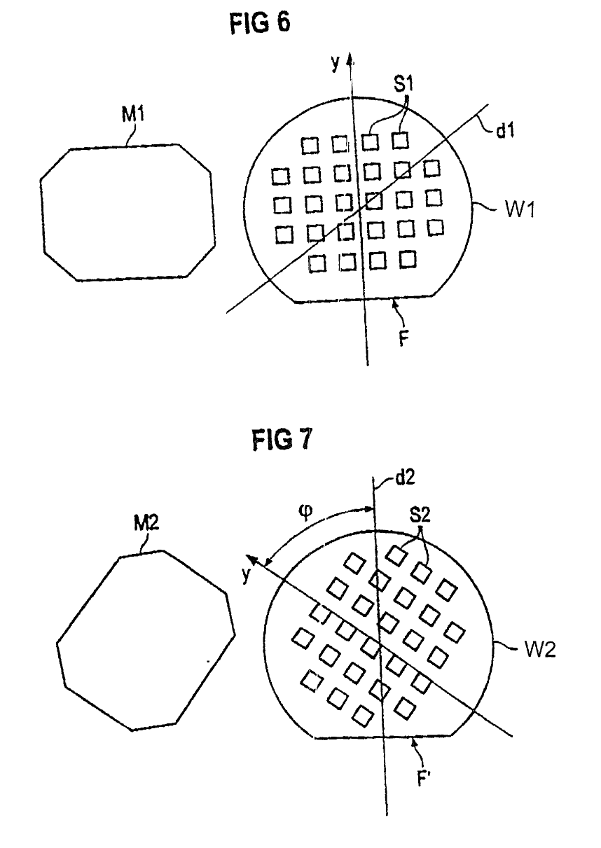

In a second exemplary embodiment, a first wafer W1 includes a second substrate of monocrystalline silicon which exhibits the shape of a flat cylinder which has been flattened on its side at a location F (flat). This location F forms a plane surface which corresponds to the (100) plane of the crystal lattice of the second substrate. The <1,0,0> direction defines a y-axis y (see FIG. 6).

The first wafer W1 is adjusted with the aid of the flattened location F in a known machine for phototechnology.

Using photoresist masks M1, a number of DRAM cell arrays Si is generated which are configured analogously to the DRAM cell configuration from the first exemplary embodiment and the chips of which are aligned as in the first exemplary embodiment with respect to the crystal lattice of the second substrate. To illustrate, a projection of the <−1,1,z> direction of the crystal lattice which defines a defect plane d1 is drawn on a surface of the second substrate in FIG. 6.

The photoresist masks M1 are introduced into the machine for phototechnology in a predetermined orientation. FIG. 6 shows an octagonal diagrammatic image of the photoresist masks. The photoresist masks M1 are applied to the first wafer W1 with the illustrated orientation of the photoresist masks M1 with respect to the crystal lattice.

In a third exemplary embodiment, a second wafer W2 includes, as in the second exemplary embodiment, a third substrate of monocrystalline silicon which exhibits a flattened location F′. In contrast to the second exemplary embodiment, the surface of the flattened location F′ corresponds to the (100) plane of the crystal lattice of the third substrate. A defect plane d2 of the third substrate extends perpendicular to the (110) plane. The defect plane d2 extends perpendicular to a surface of the third substrate which extends perpendicular to the (110) plane. As in the second exemplary embodiment, the second wafer W2 is adjusted with the aid of the flattened location F1 in the known machine for phototechnology.

Photoresist masks M2, with the aid of which a number of identical DRAM cell configurations S2 which are configured analogously to the first exemplary embodiment are generated, differ from the photoresist masks M1 from the second exemplary embodiment in that they are rotated with respect to the surface of the flattened location F′. Since the photoresist masks M2 determine the relative configuration of components of the circuit configurations, an angle between a y-axis y which is defined analogously to the first exemplary embodiment, and a projection of the defect plane d2 onto the surface of the substrate is slightly larger than the angle φ from the first exemplary embodiment. The y-axis y is drawn in FIG. 7 for clarification.

The photoresist masks M2 are introduced into the machine for phototechnology with a predetermined orientation. FIG. 7 shows an octagonal diagrammatic image of the photoresist masks M2. The photoresist masks M2 are applied to the second wafer W2 with the illustrated orientation of the photoresist mask M2 with respect to the crystal lattice.

The angle can vary between (arctan c/a) and (180°-arctan c/a).

Dimensions of the storage capacitors and of the p-n junctions and accordingly the angle can be adapted to the respective requirements.

We claim:

1. An integrated circuit configuration, comprising:
a substrate having a crystal structure with defects and defining a defect plane, said defects extending at least partly in the defect plane;
a structure provided in said substrate;
a first doped region adjoining said structure and having a first conductivity type;
a second doped region adjoining said first doped region and having a second conductivity type opposite said first conductivity type;
a boundary region provided between said first doped region and said second doped region, said boundary region forming a p-n junction; and
said structure, said p-n junction, and the defect plane being disposed such that each of a plurality of straight lines, that one of intersects and touches said structure and said p-n junction, intersects the defect plane.

2. The circuit configuration according to claim 1, wherein:
said substrate has a surface;
said structure defines a first projection onto said surface, said p-n junction defines a second projection onto said surface, the first and second projections define connecting lines therebetween;
said structure and said p-n junction are provided such that a first limiting straight line touches but does not intersect the first and second projections and such that the first limiting straight line intersects the connecting lines between the first and second projections;
said structure and said p-n junction are provided such that a second limiting straight line intersects the first limiting straight line at an intersection point thereof and touches but does not intersect the first and second projections, and such that the second limiting straight line intersects the connecting lines between the first and second projections;
the first limiting straight line and the second limiting straight line delimit two areas, said structure and said p-n junction are respectively provided in the two areas; and
the defect plane defines a third projection onto said surface, the third projection being a straight line extending outside the two areas and through the intersection point of the first and second limiting straight lines.

3. The circuit configuration according to claim 2, wherein:
said surface defines an x-axis and a y-axis perpendicular to the x-axis, the x-axis and the y-axis extend in the surface and intersect one another at the intersection point;
components are provided at the surface along lines extending parallel to one of the y-axis and the x-axis, said components are spaced from one another by periodically repetitive distances and include said structure and said p-n junction as parts;
said p-n junction and said structure are provided along the y-axis;
the two areas have respective centers, said structure and said p-n junction are disposed such that the y-axis divides the two areas in the respective centers;
the first limiting straight line includes a given part having a beginning and an end where the first limiting straight line respectively touches one of the first projection and the second projection; and
the third projection is defined by a rotation of the y-axis about an angle between arctan c/a and (180°-arctan c/a), where c is a first length of a fourth projection of the given part of the first limiting straight line onto the x-axis and where a is second length of a fifth projection of the given part of the first limiting straight line onto the y-axis.

4. The circuit configuration according to claim 3, including:
a DRAM cell configuration, said components being storage capacitors and planar transistors, said storage capacitors being provided in pairs;
said structure being a first one of said storage capacitors;
a first and a second one of said planar transistors being provided between said first one of said storage capacitors and a second one of said storage capacitors, said first one of said storage capacitors and said second one of said storage capacitors forming one of said pairs;
said first doped region acting as a first source/drain region of said first one of said transistors, said first source/drain region being connected to said first one of said storage capacitors;
said second doped region acting as a channel region for said first one of said transistors;
said second one of said planar transistors having a further channel region and having a further first region as a further first source/drain region connected to said second one of said storage capacitors;
a common second source/drain region for said first and said second one of said planar transistors, said common second source/drain region being provided between said channel region and said further channel region;
the second projection having an edge parallel to the x-axis;
said first one and said second one of said storage capacitors defining connecting lines therebetween, the connecting lines being disposed in a given region, the second projection not extending beyond the given region;
said p-n junction having a length substantially equal to the first length c; and
said p-n junction and said first one of said storage capacitors being spaced apart by a given distance, the given distance extending in a direction parallel to the y-axis and being substantially equal to the second length a.

5. The circuit configuration according to claim 1, wherein:
said substrate contains monocrystalline silicon; and
said defects are described with (−1,1,z) Burgers vectors located in the defect plane, where z is an integral number.

6. A wafer configuration, comprising:
a wafer including a substrate having a surface;
said substrate being a semiconductor disk and having a marking indicating a course of a y-axis;
said substrate having a crystal structure with defects and defining a defect plane, said defects extending at least partly in the defect plane;
a plurality of integrated circuit configurations provided in said substrate;
each of said integrated circuit configurations having components provided along lines extending parallel to one of the y-axis and an x-axis perpendicular to the y-axis, said components being provided at said surface and being spaced apart from one another by periodically repetitive distances;
a first one of said components including a structure provided in said substrate;
a second one of said components including a first doped region and a second doped region, said first doped region adjoining said structure and having a first conductivity type, said second doped region having a second conductivity type, said first and second doped regions forming a p-n junction;
said p-n junction and said structure being provided along the y-axis;
said structure defining a first projection on said surface of said substrate, said p-n junction defining a second projection on said surface of said substrate, the defect plane defining a third projection onto said surface, said first and second projections defining connecting lines therebetween;
said structure and said p-n junction being provided such that a first limiting straight line touches but does not intersect the first and second projections and such that the first limiting straight line intersects the connecting lines between the first and second projections;
said structure and said p-n junction being provided such that a second limiting straight line intersects the first limiting straight line at an intersection point thereof and touches but does not intersect the first and second projections, and said structure and said p-n junction being provided such that the second limiting straight line intersects the connecting lines between the first and second projections;
the x-axis and the y-axis extending in the surface and intersecting one another at the intersection point;
the first limiting straight line and the second limiting straight line delimiting two areas, said structure and said pn junction being respectively provided in said two areas;
said two areas having respective centers, said structure and said p-n junction being disposed such that the y-axis divides the two areas in the respective centers;
the first limiting straight line including a given part having a beginning and an end where the first limiting straight line respectively touches one of the first projection and the second projection;
the given part of the first limiting straight line defining a fourth projection onto the x-axis and a fifth projection onto the y-axis; and
the third projection being a straight line and being defined by a rotation of the y-axis about an angle between arctan c/a and (180°-arctan c/a), where c is a first length of the fourth projection and where a is a second length of the fifth projection.

7. A wafer configuration, comprising:
a wafer including a substrate having a surface;
said substrate being a semiconductor disk and having a marking indicating a course of a defect plane;
said substrate having a crystal structure with defects extending at least partly in the defect plane;
a plurality of integrated circuit configurations provided in said substrate;
each of said integrated circuit configurations having components provided along lines extending parallel to one of a y-axis and an x-axis perpendicular to the y-axis, said components being spaced apart from one another by periodically repetitive distances;
a first one of said components including a structure provided in said substrate;
a second one of said components including a first doped region and a second doped region, said first doped region adjoining said structure, said first and second doped regions forming a p-n junction;
said p-n junction and said structure being provided along the y-axis;
said structure defining a first projection on said surface of said substrate, said p-n junction defining a second projection on said surface of said substrate, the defect plane defining a third projection onto said surface, said first and second projections defining connecting lines therebetween;
said structure and said p-n junction being provided such that a first limiting straight line touches but does not intersect the first and second projections and such that the first limiting straight line intersects the connecting lines between the first and second projections;
said structure and said p-n junction being provided such that a second limiting straight line intersects the first limiting straight line at an intersection point thereof and touches but does not intersect the first and second projections, and said structure and said p-n junction being provided such that the second limiting straight line intersects the connecting lines between the first and second projections;
the x-axis and the y-axis extending in the surface and intersecting one another at the intersection point;
the first limiting straight line and the second limiting straight line delimiting two areas, said structure and said pn junction being respectively provided in said two areas;
said two areas having respective centers, said structure and said p-n junction being disposed such that the y-axis divides the two areas in the respective centers;
the first limiting straight line including a given part having a beginning and an end where the first limiting straight line respectively touches one of the first projection and the second projection;
the given part of the first limiting straight line defining a fourth projection onto the x-axis and a fifth projection onto the y-axis; and
the third projection being a straight line and being defined by a rotation of the y-axis about an angle between arctan c/a and (180°-arctan c/a), where c is a first length of the fourth projection and where a is a second length of the fifth projection.

8. A method for producing an integrated circuit configuration, the method which comprises:
providing a substrate having a marking illustrating a course of a defect plane, the substrate exhibiting a crystal structure with defects extending at least in sections in the defect plane;
providing a surface of the substrate perpendicular to the defect plane;
producing a circuit configuration in the substrate by using masks on the surface;
providing the masks as part of a layout, the layout providing components of the circuit configuration spaced apart from one another by periodically repetitive distances, and the layout providing the components of the circuit configuration along lines extending parallel to one of an x-axis and a y-axis perpendicular to the x-axis;
providing a first one of the components as a structure, the defects being generated by generating the structure;
providing a p-n junction formed by a first doped region and a second doped region, the first doped region adjoining the structure, and the p-n junction being part of a second one of the components; and
adjusting, in a machine for phototechnology, the masks with respect to the substrate by using the marking of the substrate and by rotating the layout and thus the masks with respect to a projection of the defect plane onto the surface of the substrate such that the y-axis and the projection of the defect plane enclose an angle so that a straight line, which touches but does not intersect the structure and the p-n junction, intersects connecting lines between the structure and the p-n junction and extends essentially parallel to the projection of the defect plane.

9. The method according to claim 8, which comprises producing a plurality of identical circuit configurations on the substrate.

10. A method for producing an integrated circuit configuration, the method which comprises:
providing a substrate having a marking indicating a course of a u-axis, the substrate exhibiting a crystal structure with defects extending at least in sections in a defect plane extending perpendicular to a surface of the substrate, a projection of the defect plane onto a surface of the substrate being a straight line, the u-axis and the projection of the defect plane enclosing a given angle;
producing a circuit configuration in the substrate by using masks;
providing the masks as part of a layout, the layout providing components of the circuit configuration spaced apart from one another by periodically repetitive distances, and the layout providing the components of the circuit configuration along lines extending parallel to one of a y-axis and an x-axis perpendicular to the x-axis;
providing a first one of the components as a structure, the defects being generated by generating the structure;
providing a p-n junction formed by a first doped region and a second doped region, the first doped region adjoining the structure, and the p-n junction being part of a second one of the components;
providing the structure and the p-n junction such that a straight line, which touches but does not intersect the structure and the p-n junction and intersects connecting lines between the structure and the p-n junction, and the y-axis enclose the given angle; and
adjusting, in a machine for phototechnology, the masks with respect to the substrate by using the marking of the substrate such that the y-axis defined by the layout and thus by the masks and the u-axis defined by the substrate correspond to one another.

11. The method according to claim 10, which comprises producing a plurality of identical circuit configurations on the substrate.
